(19) United States
(12) Patent Application Publication
(10) Pub. No.: US 2010/0243984 A1
(43) Pub. Date: Sep. 30, 2010

(54) Live bioelectronic cell gated nanodevice

(75) Inventors: Ravi Saraf, Lincoln, NE (US); Sanjun Niu, Mundelein, IL (US); Mehmet Inan, Lincoln, NE (US); Vikas Berry, Manhattan, KS (US)

Correspondence Address: FISH & RICHARDSON P.C., PO BOX 1022, MINNEAPOLIS, MN, 55440-1022, US

(73) Assignee: Board of Regents of University of Nebraska, Lincoln, NE (US)

(21) Appl. No.: 11/550,705

(22) Filed: Oct. 18, 2006

Related U.S. Application Data
(60) Provisional application No. 60/727,806, filed on Oct. 18, 2005.

(51) Int. Cl. H01L 51/10; H01L 51/40

(52) U.S. Cl. 257/9; 438/1; 977/773; 257/E51.004

(57) ABSTRACT

This invention is directed toward a bioelectronic cell gated nanodevice. The bioelectronic cell gated nanodevice comprises a plurality of bioelectric cells deposited on a fiber of a nanodevice. The bioelectronic cells of the nanodevice act as a gate, allowing current to be transmitted when the bioelectronic cells are exposed to an actuating chemical. The present invention also provides methods for constructing such a device.

### CROSS-REFERENCE TO RELATED APPLICATIONS

This application claims the benefit of U.S. Provisional Application Ser. No. 60/727,806, filed Oct. 18, 2005 and entitled “Live Bioelectronics: Live Microorganism or Cell Gated Transistor,” which is hereby incorporated herein by reference. This application is related to patent application Ser. No. 11/491,840 entitled “Fabrication of Ultra Long Necklace of Nanoparticles” filed on Jul. 24, 2006.

### STATEMENT REGARDING FEDERALLY SPONSORED RESEARCH OR DEVELOPMENT

None.

### BACKGROUND OF THE INVENTION

Electronic devices at nanoscale dimensions have the potential of achieving high performance with significantly lower power consumption compared to current devices. The range of their switching voltages and operating currents also opens the possibilities for coupling the nanoscale devices with live microorganisms. This area of bioelectronics potentially permits leveraging nature's nanodevice systems to achieve electronic systems with highly complex functionalities not feasible in current microelectronics. In principle, coupling between a microorganism and a nanodevice creates a platform for electronic devices that can be locally powered by living microorganisms consuming biodegradable “food” rather than caustic batteries. One application of these “intelligent systems” driven by microorganisms is a highly selective, highly sensitive biological and chemical sensor to detect a variety of specific virus, bacteria, proteins, etc. on a single chip.

The advancement of this technology, however, has been hindered due to the difficulty associated with electronically coupling the biology of the microorganism with a nanodevice system. Thus, a system and method for coupling the biology of a microorganism to a nanodevice system made of nanoparticles is desirable.

### SUMMARY OF THE INVENTION

The present invention generally provides a system and method for coupling live microorganisms to a nanodevice system where the metabolic function of the cell controls the operation of the nanodevice. Generally, the present invention involves developing cells for use in a bioelectronic cell gated nanodevice and depositing a plurality of the bioelectronic cells onto the gated nanodevice. Exposing the bioelectronic cells to one or more actuating chemical changes of the cells electronic properties. For example, exposing the live microorganism to actuating chemicals can result in the current through the nanodevice increasing. Thus, the microorganism effectively gates the electron transport through the nanodevice system. Because the system is fully integrable, the concept applies to coupling a variety of organisms sensitive to specific moieties.

### BRIEF DESCRIPTION OF THE SEVERAL VIEWS OF THE DRAWINGS

The present invention is described in detail below with reference to the attached drawing figures, wherein:

FIG. 1 illustrates a nanodevice environment for a bioelectronic cell gated nanodevice in accordance with the present invention schematically;

FIG. 2 illustrates a method for constructing a nanodevice nanoparticle necklace in accordance with the present invention;

FIG. 3 illustrates the electrical properties of a nanodevice nanoparticle necklace in accordance with the present invention;

FIG. 4 further illustrates the electrical properties of a nanodevice nanoparticle necklace in accordance with the present invention;

FIG. 5 illustrates a nanodevice nanoparticle necklace having nanoparticles of a first type and a second type in accordance with the present invention;

FIG. 6 illustrates a method for constructing a nanodevice nanoparticle necklace having nanoparticles of a first type and a second type in accordance with the present invention;

FIG. 7 illustrates the electrical properties of a nanodevice nanoparticle necklace in accordance with the present invention;

FIG. 8 further illustrates the electrical properties of a nanodevice nanoparticle necklace in accordance with the present invention;

FIG. 9 further illustrates the electrical properties of a nanodevice nanoparticle necklace in accordance with the present invention;

FIG. 10 further illustrates the electrical properties of a nanodevice nanoparticle necklace in accordance with the present invention;

FIG. 11 illustrates a bioelectronic cell gated nanodevice in accordance with the present invention schematically;

FIG. 12 illustrates the electrical properties of a bioelectronic cell gated nanodevice in accordance with the present invention;

FIG. 13 illustrates a method for constructing a bioelectronic cell gated nanodevice in accordance with the present invention; and

FIG. 14 illustrates a method for constructing a bioelectronic cell gated nanodevice having a nanoparticle necklace in accordance with the present invention.

### DETAILED DESCRIPTION OF THE INVENTION

The present invention provides a system and method for coupling microorganisms to a nanodevice system made from nanoparticles. An exemplary embodiment of a nanodevice environment is also described herein, although the description of a nanodevice environment is in no way intended to limit the applicability of the system and method of the present invention to other types of nanodevice environments. Throughout this application, the terms “microorganism” and “cell” and variations thereof are used interchangeably to describe various live bioelectronic elements of a nanodevice.

One exemplary nanodevice embodiment described herein uses approximately 5000 Au particles of diameter of approximately 10 nm. In this exemplary embodiment, sites in the necklace are isolated “islands” with SET characteristics that lead to an extremely high, robust and reproducible V_{CB} of about 2.2 V. The self-assembly is a simple process where the nanoparticles agglomerate at an edge of a polymer fiber to produce a 1-D percolating channel. A simple model based on a composite structure of “ohmic channels” and single nanoparticle “islands” explains the large V_{CB} behavior. For longer deposition time, there is an annealing effect such that the currents jump by approximately 5-fold and a sharp Coulomb staircase behavior is observed. The charging energy is same as the pure blockade behavior corresponding to V_{CB} of approximately 2.2V and the nanoparticle (island) resistance is consistent with reported single-nanoparticle SET devices operating at room temperature.

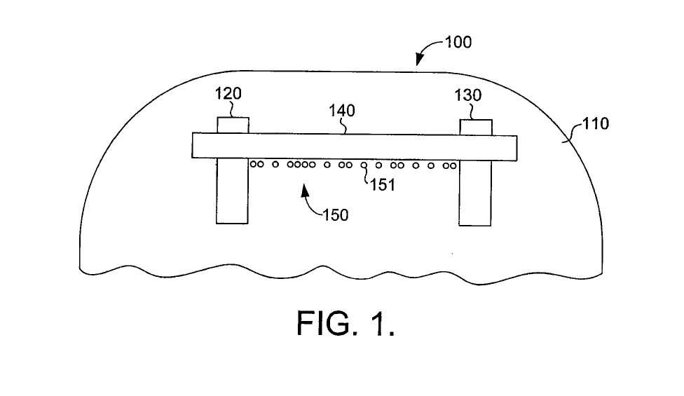

FIG. 1 illustrates an example of a nanoparticle necklace 100 in accordance with the present invention. FIG. 1 is not to scale. A substrate 110 may be comprised of a layer of SiO₂ over a Si wafer. A pair of electrodes 120, 130 may comprise a set of 1 mm wide Au electrodes spaced at 50 μm apart on substrate 110, although other types and sizes of electrodes may be used. Fiber 140 may comprise a polystyrene fiber extending across the pair of electrodes 120, 130, although other types of fibers may be used. A plurality 150 of nanoparticles, such as nanoparticle 151, are adhered to fiber 140 between first electrode 120 and second electrode 130. While plurality 150 of nanoparticles may be selected to possess any type of electrical and/or chemical properties desired, in the exemplary embodiment nanoparticles of Au having a diameter of approximately 10 nm are used.

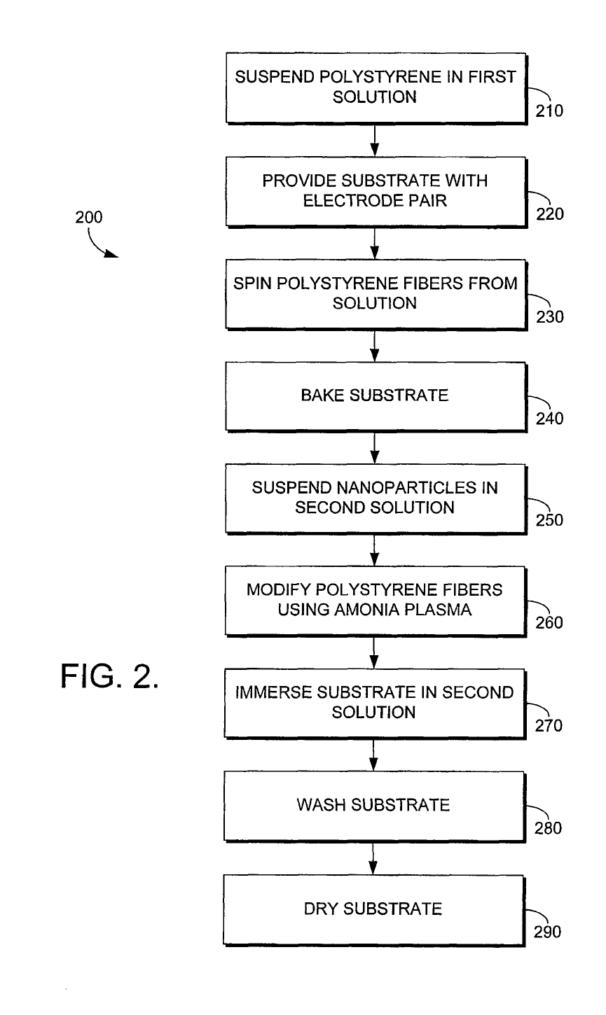

FIG. 2 illustrates a method 200 for fabricating a necklace of nanoparticles in accordance with the present invention. In step 210 fiber material, such as polystyrene, may be suspended in a first solution. In step 220 a substrate, such as described above with regard to FIG. 1, having an electrode pair may be provided. In step 230 the fibers may be spun from the solution. For example, polystyrene fibers may be spun on a substrate using spindle rotating at approximately 5000 rpm from an approximately 15% solution in toluene. The diameter of the fibers may be approximately 600 nm. The fibers may cross a set of 1 mm wide Au electrodes spaced at 50 μm on the substrate. The substrate and fibers may be subsequently baked in vacuum of approximately 1 mtorr at approximately 120° C. for about 20 minutes to flatten the fibers at the fiber/substrate interface. In step 250 nanoparticles may be suspended in a second solution. The suspended nanoparticles may be negatively charged 10 nm Au particles. The second solution in which the nanoparticles are suspended may be an aqueous solution at pH of approximately 4. In step 260 the polystyrene fiber surface may be modified with an amine group by exposure to ammonia plasma for approximately 20 seconds. After step 260 method may immediately proceed to step 270, in which the substrate and fibers may be immersed in the second solution containing suspended nanoparticle. The immersion of step 270 may last for approximately 8 hours. In step 280 the substrate and structures on the substrate may be washed thoroughly with water. In step 290 the substrate and structures on the substrate may be air-dried. One skilled in the art will appreciate that the temperatures, pressures, pHs, time periods, solution types, and material types described above are approximate only, and may be varied without departing from the scope of the present invention.

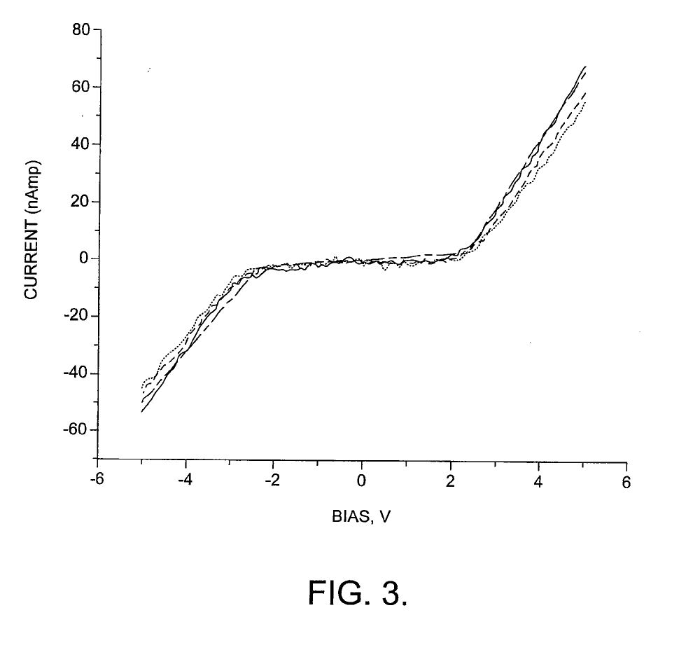

FIG. 3 illustrates the electrical properties of a nanoparticle necklace in accordance with the present invention. Typical characteristics of a nanoparticle necklace in accordance with the present invention include: (i) a highly well defined V_{CB} at about 2.2 V; (ii) the I-V is robust over several I-V cycles spanning multiple days; (iii) virtually no hysteresis is observed; (iv) the behavior after the threshold voltage is linear, indicating transport in a 1-D necklace; (v) most significant are the switching characteristics: over an excursion of 1.7 to 2.7 V the current changes by 6.5 fold (from 2 V to 6 V it changes 31 fold, from 1 to 2V the increase is 2 fold, while from 2 to 3 V, the increase is 9 fold); and (vi) the operating current is high, in 10¹ nA range.

The capacitance of a nanoparticle of diameter d, surrounded by organic tunneling barrier of dielectric constant, ∈, is cₙₚ=2π∈∈₀d, where ∈₀ is the permittivity in vacuum. Therefore, for a single nanoparticle device of d=10 nm, the energy to charge the particle with a second electron is, U=e2/(21 tssod)˜0.065 eV corresponding to about 3 kT at room temperature. Thus, the passage of electron above a threshold bias of V_{CB} of about 0.065 V will not be blocked by Coulomb repulsion. The 50 fold increase in the V_{CB} compared to single 10 nm particle measurements is explained as follows.

Referring again to FIG. 1, the nanoparticle necklace may be thought of as being composed of “clusters” with identical single nanoparticle “islands” marked. The “clusters” are closely packed nanoparticles, perhaps aided by some adjacent rows of nanoparticles, where the tunneling resistance is low resulting in a close to Ohmic behavior similar to high density monolayer of nanoparticles. The islands are a single nanoparticle spaced by a larger gap leading to SET characteristics. For bias below V_{CB}, the necklace can be assumed to be a pure capacitor with a capacitance, cₜ=cₙₚ/n , where n is the number of islands, and cₙₚ is the individual capacitance of the nanoparticle residing in the island. At V_{CB} corresponding to charging each of the islands with a single electron charge, e, is given by ne/cₜ or n²e/cₙₚ. Thus, the V_{CB} corresponding to single nanoparticle is amplified by n² in the 1-D necklace. For bias above V_{CB}, the current rises linearly following Ohms law with an effective resistance of Rₜ=n(Rₙₚ+R_{c}), where R_{c} and Rₙₚ are cluster and the nanoparticle island resistances, respectively. At a total bias, V, between the electrodes leading to current I, the resistive drop across the island nanoparticle, Rₙₚ is given by, f(V−V_{CB})/n=IRₙₚ, where f=Rₙₚ/(Rₙₚ+R_{c}). Thus the I-V characteristics for V>V_{CB} becomes, V=V_{CB}+IRₜ which is consistent with observations in FIG. 3. This equation is similar to Ia[V/V_{CB}−1]^{ζ}, where ζ=1 for 1-D arrays. Assuming, an ∈˜3 (reasonable for organic surrounding), cₙₚ˜2.5×10⁻¹⁸ F. For a measured V_{CB} of 2.2V, the number of SET islands n=(cₙₚV_{CB}/e)^{0.5} are about 6. Within 10%, it is reasonable to neglect R_{c} relative to Rₙₚ, i.e., f approximately 1. Based on the measured Rₜ of approximately 42.2 MΩ, the estimated value of SET resistance, Rₙₚ≈Rₜ/n˜7 MΩ, which is reasonable compared to the reported values.

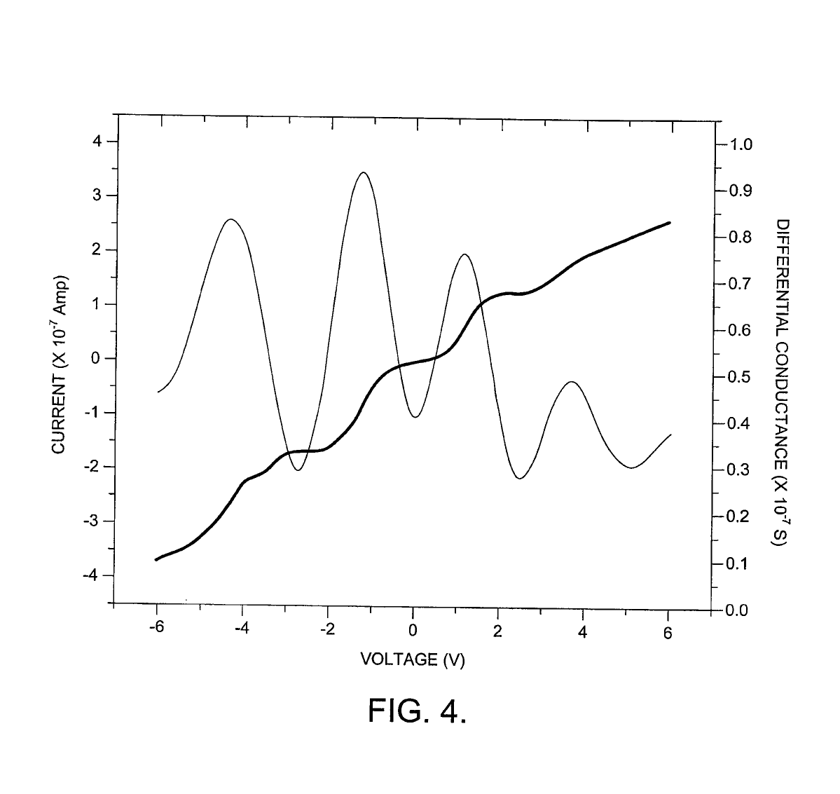

FIG. 4 shows an I-V of Au nanoparticle for 12 hour deposition exhibiting a Coulomb staircase effect. The periodic modulation of the differential conductance is about 2.2 V, indicating that the charging energy is identical to the Coulomb staircase, i.e., n˜6. The I-V characteristics are similar to previously reported Coulomb staircases in single nanoparticle at room temperature, however the currents are 1 to 3 orders of magnitude larger and most importantly the switching voltage, V_{CB} is increased form <0.1 V to 2.2V (i.e., charging energy is about 100 kT). Interestingly, contrary to theoretical models that predict the coulomb staircase cannot be obtained in isolated 1-D system due to significant smearing effects, a sharp staircase indicating high coherence in charge transport among the islands was observed.

The present invention further provides an approach to assemble a necklace of nanoparticles along an edge of a dielectric to fabricate a switching device that exhibits Coulomb staircase and blockade effects at room temperature. The switching voltage, V_{CB}˜n² can be tailored by controlling the number of isolated islands in the necklace during the fabrication process. The following three features open the possibility of self assembling practical nanodevices based on coulomb blockade effect: (i) the I-V characteristics are robust (i.e., high reproducibility, large operating currents, and sharp blockade effect); (ii) V_{CB} is close to about 100 kT at room temperature; and (iii) in principle the edge may be produced by patterning dielectric by lithographic techniques. With clever surface modification of edge and lithographic methods of patterning the edges, complex networks of nanoparticle necklaces could be fabricated to obtain robust digital devices operating at room temperature.

The present invention provides a method of making a necklace nanoparticles supported on an edge of a polymer fiber or a film. The necklace is a one-dimensional row of nanoparticles in contact with each other via a thin layer of organic substance, such as polymer and/or surfactant coating. The organic coating lets the electron “tunnel” through it but provides a small resistance. This tunneling barrier and small size of the nanoparticles makes the necklace a single-electron tunneling (SET) device. In other words, at low voltage across the necklace ends, the current is virtually zero because the electrons cannot pass through. As the voltage is above a threshold voltage, V_{T} the current takes-off. This phenomenon of “coulomb blockade” is well known for over 4 decades, and can be used to build devices such as transistor, electronic switches.

The nanoparticle necklace in accordance with the present invention has imbedded SET devices, and the long chain nature provides the “circuitry” to connect to power and signal input/output interconnection terminals which may be electrodes. The necklace is a very versatile and general concept and may utilize more than one type of nanoparticles. Methods in accordance with the present invention may be used to build functional electronic switches and diodes. A necklace in accordance with the present invention can be shaped to any form required by the circuitization scheme just like copper lines on printed circuit boards.

A self-assembled nanoparticle necklace may be used as a basic electronic element in accordance with the present invention. Nanoparticle necklaces may comprise any number of types of nanoparticles. For exemplary purposes herein, nanoparticle necklaces having only a first type and a second type of nanoparticles are described, but further types of nanoparticles may be used. The types of nanoparticles used may be based upon their electrical properties (conducting, insulating, or semiconducting), although other properties such as size or chemistry may be considered. A polymer fiber maybe used as a scaffold to direct the assembly of a one-dimensional percolating structure for a nanoparticle necklace. The length and shape of the necklace may be determined by the polymer fiber.

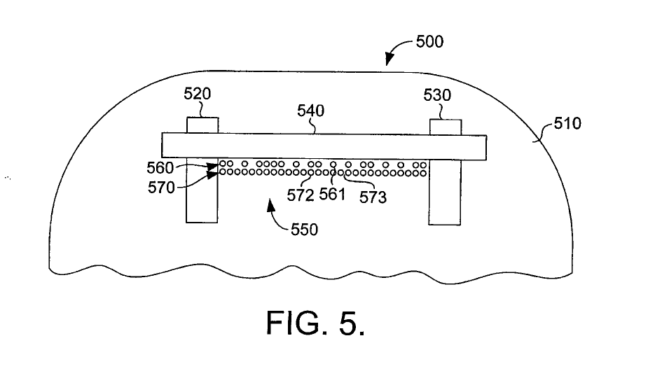

Referring now to FIG. 5, a nanoparticle necklace 500 utilizing nanoparticles of a first type and nanoparticles of a second type is illustrated. FIG. 5 is not to scale. A substrate 510 maybe comprised of a layer of SiO₂ over a SI wafer. A pair of electrodes 520, 530 may comprise a set of one millimeter wide AU electrodes spaced at 50 micrometers apart on substrate 510, although other types and sizes of electrodes may be used. Fiber 540 may comprise a polystyrene fiber extending across the pair of electrodes 520, 530, although other types of fibers may be used. A plurality of nanoparticles of a first type 560, such as nanoparticles 561, adhere fiber 540 between first electrode 520 and second electrode 530. While plurality of nanoparticles of a first type 560 may be selected to possess any type of electrical and/or chemical properties desired, in the exemplary embodiment nanoparticles of Au having a diameter of approximately 10 nanometers are used. Although the Au particles as illustrated in FIG. 5 are deposited on the whole fiber, the high density deposition that electrically percolates is only at the edge. The inter-particle distance toward the center of the fiber is too high to form conducting channels. The fiber can be lifted off the surface by etching the SiO₂ in HF. A plurality of nanoparticles of a second type 570, such as nanoparticles 572, 573, are adhered to the nanoparticles of the first type 560. While the plurality of nanoparticles of a second type 570 may be selected to possess any type of electrical and/or chemical properties desired, in the exemplary embodiment semiconducting nanoparticles of CdS having a diameter of approximately three nanometers are used.

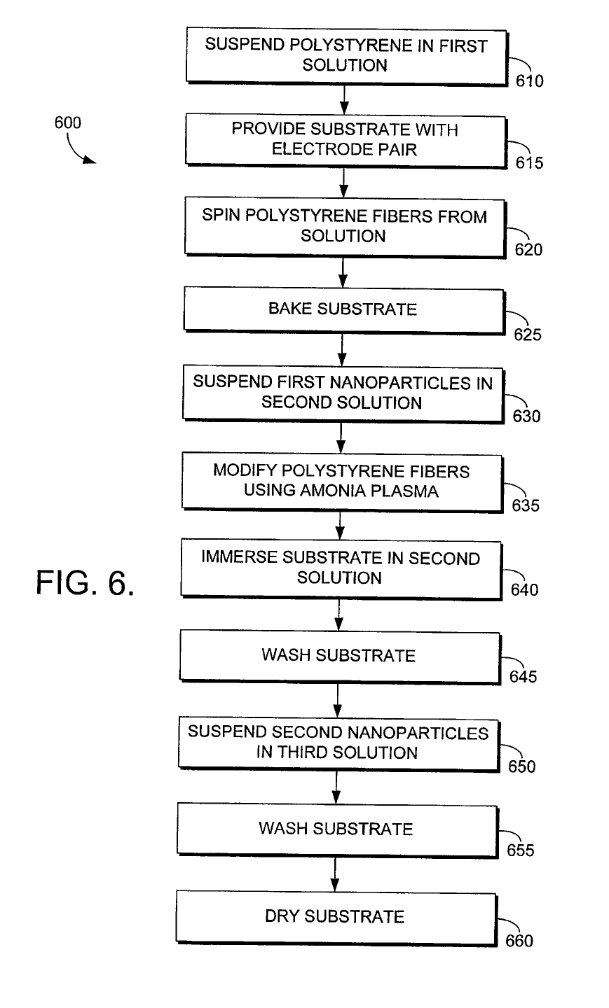

FIG. 6 illustrates a method 600 for fabricating a necklace of nanoparticles in accordance with the present invention. In step 610 fiber material, such as polystyrene, may be suspended in a first solution. In step 615 a substrate, such as described above with regard to FIG. 5, having an electrode pair may be provided. In step 620 the fibers may be spun from the solution. For example, polystyrene fibers may be spun on a substrate using spindle rotating at approximately 5000 rpm from an approximately 15% solution in toluene. The diameter of the fibers may be approximately 600 nm. The fibers may cross a set of 1 mm wide Au electrodes spaced at 50 μm on the substrate. The substrate and fibers may be subsequently baked in vacuum of approximately 1 mtorr at approximately 120° C. for about 20 minutes to flatten the fibers at the fiber/substrate interface in step 625. In step 630 nanoparticles of a first type may be suspended in a second solution. The suspended nanoparticles of a first type may be negatively charged 10 nm Au particles. The second solution in which the nanoparticles are suspended may be an aqueous solution at pH of approximately 4. In step 635 the polystyrene fiber surface may be modified with an amine group by exposure to ammonia plasma for approximately 20 seconds. After step 635 method 600 may immediately proceed to step 640, in which the substrate and fibers may be immersed in the second solution containing suspended nanoparticles of a first type. The immersion of step 640 may last for approximately 8 hours. In step 645 the substrate and structures on the substrate may be washed thoroughly with water. In step 650 the substrate and structures on the substrate may be immersed in a solution containing nanoparticles of a second type. For example, the nanoparticles of a second type maybe positively charged 3 nm CdS particles. The substrate and structures on it may then be washed in step 655 and dried in step 660. One skilled in the art will appreciate that the temperatures, pressures, pHs, time periods, solution types, and material types described above are approximate only, and may be varied without departing from the scope of the present invention.

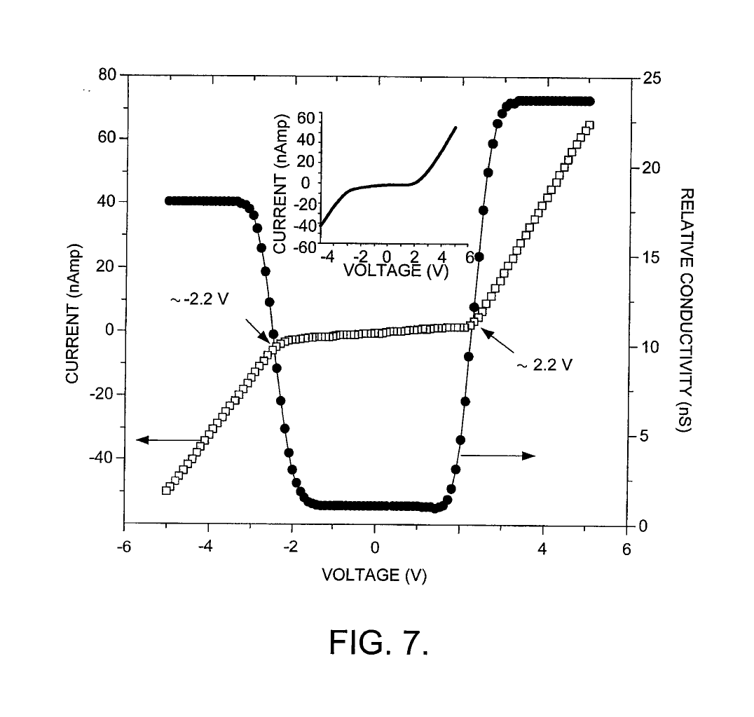

FIG. 7 illustrates the electrical properties of a nanoparticle necklace in accordance with the present invention. All the currents measured are divided by two to represent the characteristics of a single necklace. FIG. 7 shows a typical I-V characteristic of 10 mm Au particles spanning over a 50 μm gap. The I-V characterization of the electrically percolating necklace of 5,000 particles was performed at a step size of 100 mV, and the instrument resolution for currents measurement was 1 pA. The measurements were performed in a vacuum (10⁻⁵ torr) at room temperature.

The following points are salient characteristics of the device inferred from FIG. 7. First, there is a well-defined V_{CB} is at ˜2.2 V. Second, the I-V is robust over several I-V cycles spanning over a couple of days (see inset). Third, as shown in the inset, virtually no hysteresis was observed. Fourth, a linear behavior is observed beyond the threshold voltage, indicating transport in a one dimensional necklace. Fifth, over an excursion from 2V to 3V or 6V, the current change was 9-fold or 31-fold, respectively. Sixth, the operating current was high, in the STET nA range, compared to single-nanoparticle devices, with the STM tip interconnection indicating good contact resistance between the necklace and the Au electrode pads.

The 30-fold enhancement in V_{CB} relative to a single 10 nm nanoparticle device can be explained by considering the necklace as a composite structure composed of percolating one dimensional clusters with isolated single-nanoparticle “islands”. The clusters are closely packed nanoparticles, perhaps aided by some adjacent rows of nanoparticles, where the tunneling resistance was low, resulting in an Ohmic behavior at room temperature similar to a high density monolayer of nanoparticles. The isolated, single-nanoparticle islands were spaced by a larger gap, leading to SET characteristics. The capacitance of the nanoparticle island of diameter d, surrounded by an organic tunneling barrier of dielectric constant, ∈, is cₙₚ=2π∈∈₀d, where ∈_{ö} is the permittivity in the vacuum. Thus, for a single-nanoparticle device of d=10 nm, the energy to charge the particle with a second electron is U=e²/(2π∈∈₀d)˜0.065 eV, corresponding to ˜3 kT at room temperature. Accordingly, the passage of an electron above a threshold bias of V_{CB}˜0.065 V will not be blocked by coulomb repulsion. However, if the necklace has n islands, the charging energy is U_{T}=e²/cₜ=n[e²/cₙₚ]. Thus, V_{CB} given by e/cₜ (or n[e/cₙₚ]) is amplified by n times relative to single particle. From FIG. 7, for measured V_{CB} of 2.2 V, n is approximately 36. For a bias above V_{CB}, the current rises linearly following Ohms law with an effective resistance of Rₜ=n(Rₙₚ+R_{c}), where R_{c} is a cluster and Rₙₚ is the nanoparticle island resistances. At a total bias V between the electrodes leading to current I, the resistive drop across the island nanoparticle, Rₙₚ is given by f(V−V_{CB})/n=IRₙₚ, where f=Rₙₚ/(Rₙₚ+R_{c}). Thus, the I-V characteristics for V>V_{CB} become, V=V_{CB} IRₜ which is consistent with observations in FIG. 7. The I-V characteristics are similar to I a [V/V_{CB}−1]^{ζ}, where ζ=1 implies 1D arrays. Assuming ∈˜3, which is reasonable for the organic surrounding, then cₙₚ˜2.5×10⁻¹⁸ F. For a measured V_{CB} of 2.2V, the number of SET islands n=(cₙₚV_{CB}/e)^{0.5} is ˜6. Within 10% error, it is reasonable to neglect R_{c} relative to Rₙₚ, i.e., f˜1. Based on the measured Rₜ≈Rₜ/n˜7 M′Ω is reasonable compared to reported values.

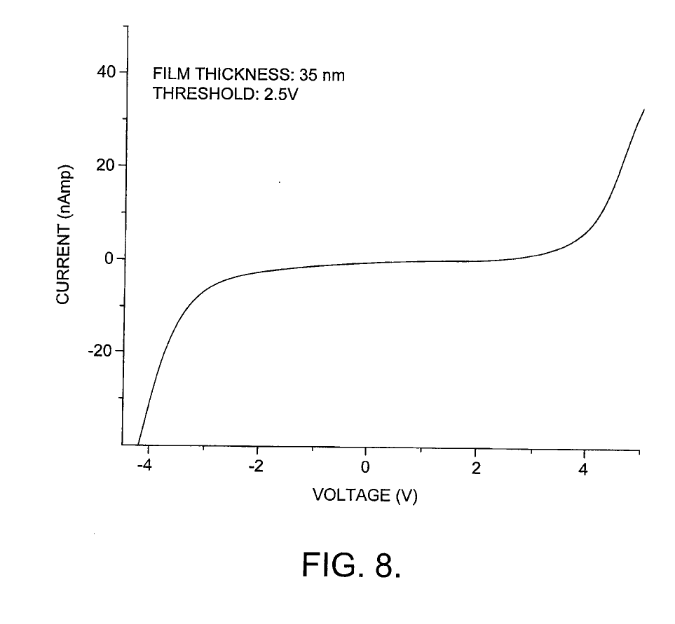

FIG. 8 illustrates the electrical behavior of a necklace of a 10 nm Au nanoparticle at the edge of an approximately 35 nm thick polymer film. The film was spin-coated on a Si wafer coated with a water soluble polymer and, then, floated on water. The floated film was placed on the substrate with Au electrodes using a standard method to fabricate a layer-by-layer, polymer-thin, film coating with nanometer-scale thickness. The subsequent process was similar to the fiber process. Similar to the fiber, the nanoparticle deposition on the fiber was sparse; however, a 1D necklace similar to the fiber was formed at the edge. The I-V behavior in FIG. 8 clearly shows similar coulomb blockade behavior indicating single-electron transport process.

Owing to the symmetry of the necklace, diode-like behavior would seem unlikely. However, it was discovered that by electrically annealing the necklace by applying bias on one electrode and leaving the other floating, it is possible to polarize the electrical conductivity in one direction. In the annealing process, one electrode was subjected to approximately 50 V with the other electrode left open. An Au/CdS nanoparticle necklace formed by step-wise co-deposition of the two particles followed by electric-annealing on one of the two electrodes would resemble necklace 500 illustrated in FIG. 5. The relative number fraction of CdS could be approximately 10%. Due to annealing, the Au/insulator/CdS/insulator/Au Schottky junctions would be asymmetric, leading to a diode-like I-V characteristic with no hysteresis. The resulting diode was highly reproducible and robust over 10 cycles showing no systematic hysteresis.

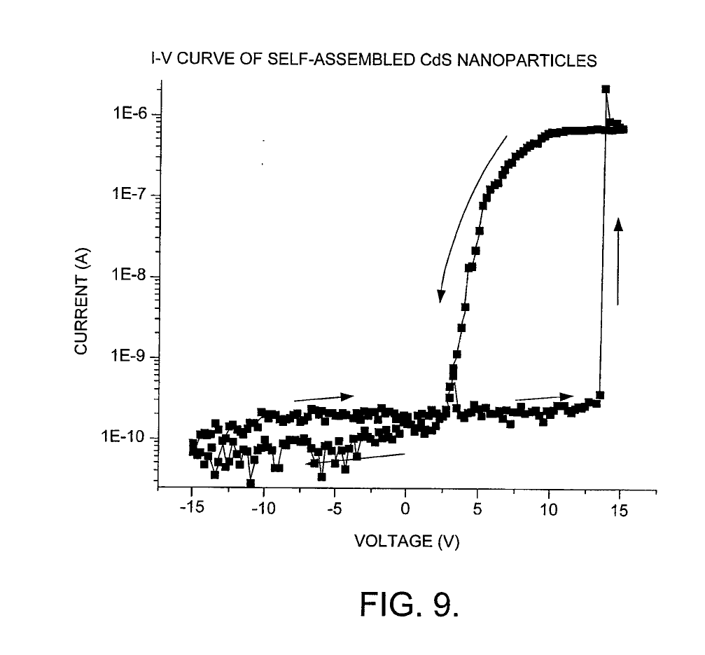

FIG. 9 illustrates the I-V characteristics of an Au (10 nm) and CdS (3 nm) necklace where the latter forms a “series” of Schottky devices along the necklace. The large switching current is observed only when the CdS is tethered with a highly ionic organic surfactant. Potentially the highly ionic surfactant stores charge, leading to blockade effect. In this molecular electronic device, organic molecule being the surfactant, robust switching with current ratio between the ON and OFF state of ˜10⁴ is obtained. Here, also, the necklace was electrically annealed in the forward direction. As can be seen, switching jump is robust. After 10V, the curve retraces well with no hysteresis.

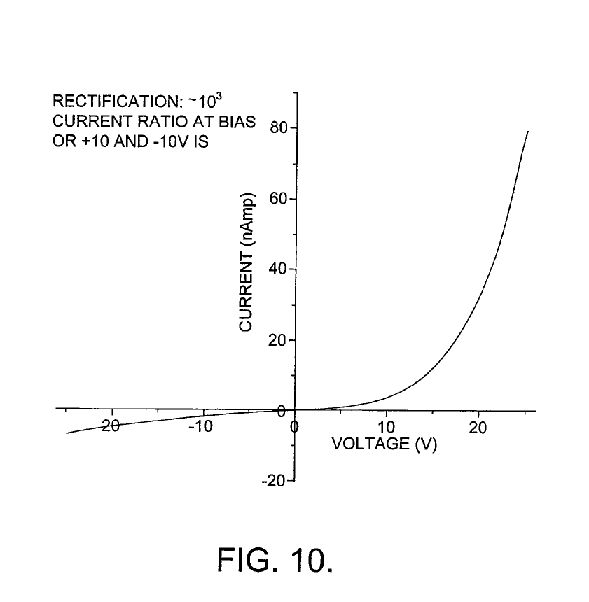

FIG. 10 illustrates the I-V characteristics of a Schottky necklace composed of Au and CdS nanoparticles spanning a 50 micrometer gap between electrodes. The ratio between current in forward bias (+10 V) and reverse bias (−10 V) is approximately 10³. The ratio increases to approximately 10⁴ for operation between +5 V and −5 V. Nanoparticle electronic devices, such as those described above, may be used in conjunction with cells to create a live bioelectronic cell gated nanodevice in accordance with the present invention. One skilled in the art will realize that other nanoparticle electronic devices may also be used in conjunction with the present invention. One skilled in the art will further appreciate that the cells used in conjunction with the present invention may vary from those described in the examples below and may include any type of cell from any single-cellular or multi-cellular organism without departing from the scope of the present invention.

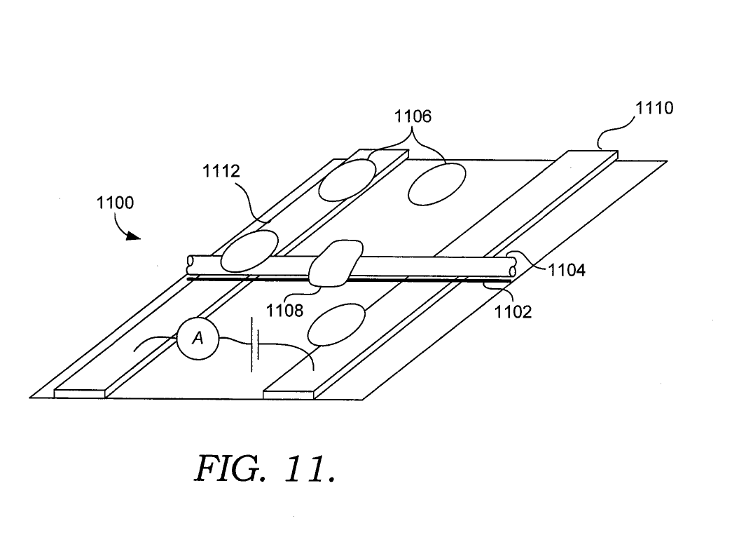

Referring now to FIG. 11, a bioelectronic cell gated nanodevice in accordance with the present invention is illustrated. FIG. 11 is not to scale. A pair of electrodes 1110, 1112 may comprise a set of 1 mm wide Au electrodes spaced at 50 μm apart, although other types and sizes of electrodes may be used. Fiber 1104 may comprise a polystyrene fiber extending across the pair of electrodes 1110, 1112, although other types of fibers may be used. Fiber 1104 may alternatively be removed during the fabrication process. In one embodiment, a plurality of microorganisms 1106 are deposited across the nanodevice 1100. The microorganisms are deposited non-selectively on the nanodevice, but only the microorganisms on the fiber 1104 and necklace 1102 at gate 1108 contribute to the electronic functionality of the device. While the plurality of microorganisms 1106 may be selected to possess any type of properties, in one embodiment of the present invention, a methylotrophic yeast (Pichia pastoris) is used.

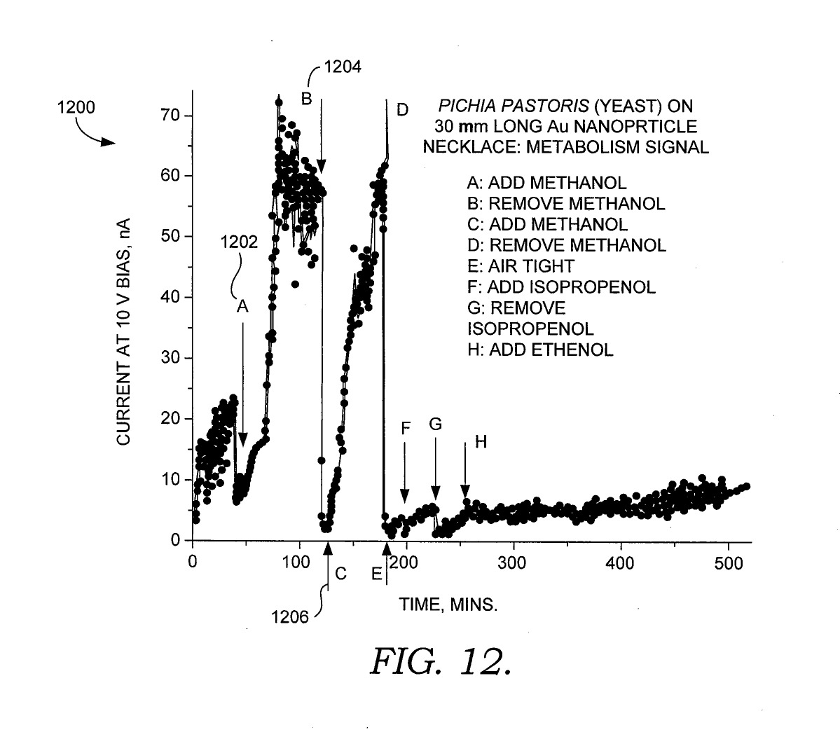

Referring now to FIG. 12, the electrical properties of one embodiment of a bioelectronic cell gated nanodevice, in accordance with the present invention are depicted graphically. In this embodiment, genetically prepared yeast used to metabolize methanol is deposited on a single Au nanoparticle necklace as will be understood by one of ordinary skill in the art. In this embodiment, the yeast is grown in media containing methanol as a carbon source for approximately twenty-four hours prior to deposition on the fiber 1104 and necklace 1102. The graphical representation of FIG. 12 depicts the current monitored as the yeast is subjected to various environments. In the present embodiment, the yeast was first exposed to methanol vapors between time points 1202 and 1204 on the graph. Exposure of the yeast to methanol vapors between time points 1202 and 1204 results in a drastic increase in current. The subsequent removal of the methanol vapors between time points 1204 and 1206 results in an equally drastic reduction in current. In this embodiment, when the methanol grown cells are exposed to iso-proponal, which cannot be used as a carbon source, no change takes place. Moreover, when the cells are exposed to ethanol, which can be sued as a carbon source, no changes take place because the cells are specifically primed for only methanol utilization. The large increase in current and the coulomb blockade nature of the necklace demonstrates the gating function that the cell performs on electron transport. In one embodiment of the present invention, the cells remain alive and responsive for at least three days on the device without any liquid nutrients, allowing the nanodevice to be stored and “primed” before use. As will be appreciated by one of ordinary skill in the art, the present invention is in no way limited to a methanol primed yeast; rather the present invention applies to the coupling of any type of microorganism with an electronic nanodevice.

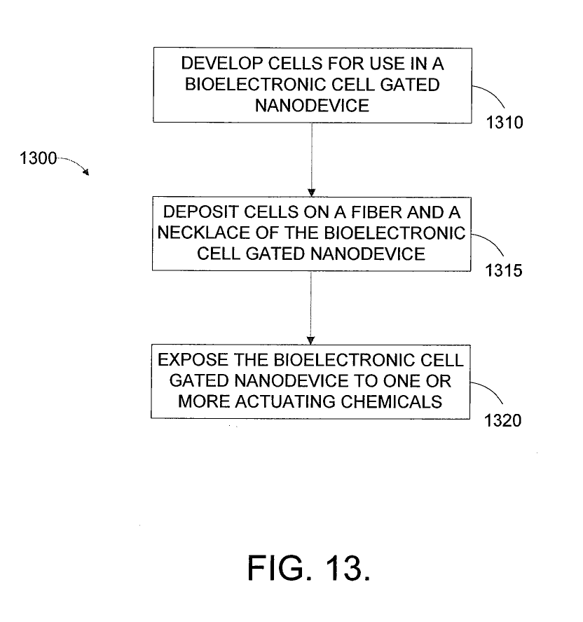

FIG. 13 illustrates a method 1300 for fabricating a bioelectronic cell gated nanodevice in accordance with the present invention. In step 1310, cells are developed for use in a bioelectronic cell gated nanodevice. In one embodiment of the present invention, the cells are methylotrophic yeast cells primed for methanol utilization. However, the present invention is not limited to methylotrophic yeast cells. Rather, any type of microorganism can be used. In step 1315, cells are deposited on a fiber and necklace of the bioelectronic cell gated nanodevice. In one embodiment of the present invention the microorganisms are deposited non-selectively on the nanodevice and only the microorganisms on the fiber and necklace contribute to the functionality of the device. In step 1320, the bioelectronic cell gated nanodevice is exposed to one or more actuating chemicals. In one embodiment of the present invention, the actuating chemical is methanol, causing the cells to drastically alter electron transport as illustrated in FIG. 12. The present invention, however, is not limited to methanol as an actuating chemical. Rather, various other chemicals can be used in association with a variety of microorganisms that have utility independently or in combination as single-molecule sensors.

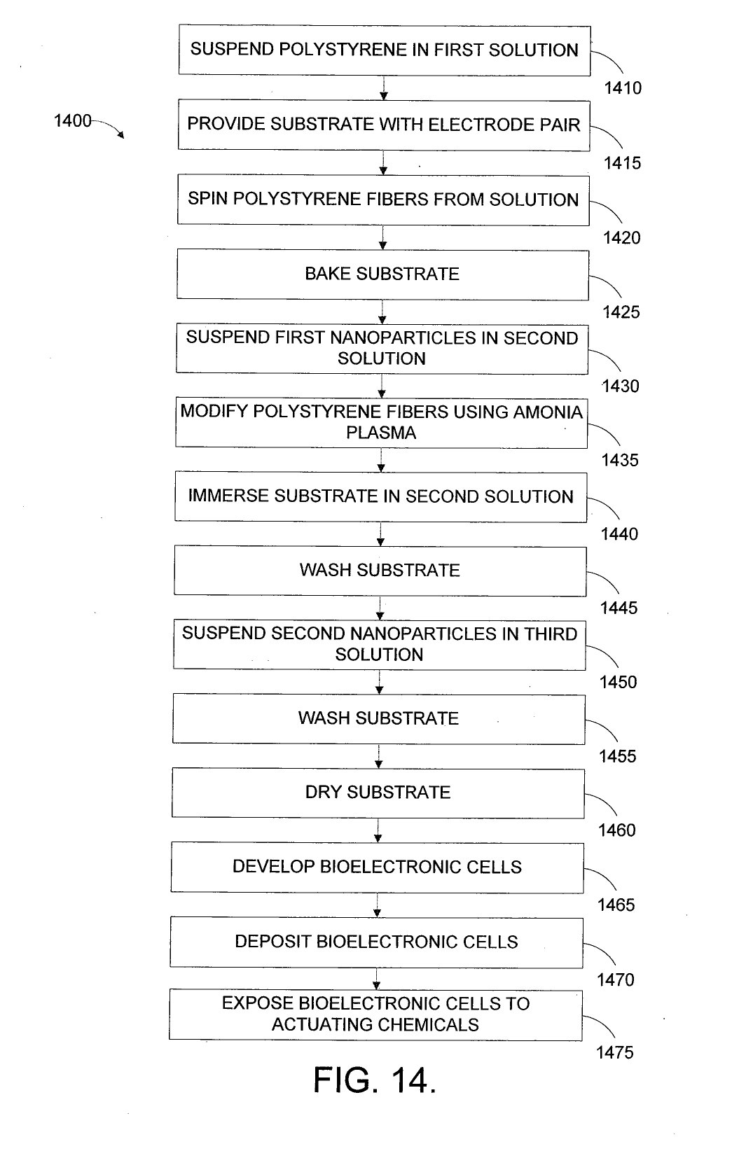

FIG. 14 illustrates a method 1400 for fabricating a bioelectronic cell gated nanodevice in accordance with the present invention. In step 1410 fiber material, such as polystyrene, may be suspended in a first solution. In step 1415 a substrate, such as described above with regard to FIG. 5, having an electrode pair may be provided. In step 1420 the fibers may be spun from the solution. For example, polystyrene fibers may be spun on a substrate using spindle rotating at approximately 5000 rpm from an approximately 15% solution in toluene. The diameter of the fibers may be approximately 600 nm. The fibers may cross a set of 1 mm wide Au electrodes spaced at 50 μm on the substrate. The substrate and fibers may be subsequently baked in vacuum of approximately 1 mtorr at approximately 120° C. for about 20 minutes to flatten the fibers at the fiber/substrate interface in step 1425. In step 1430 nanoparticles of a first type may be suspended in a second solution. The suspended nanoparticles of a first type may be negatively charged 10 nm Au particles. The second solution in which the nanoparticles are suspended may be an aqueous solution at pH of approximately 4. In step 1435 the polystyrene fiber surface may be modified with an amine group by exposure to ammonia plasma for approximately 20 seconds. After step 1435 method 1400 may immediately proceed to step 1440, in which the substrate and fibers may be immersed in the second solution containing suspended nanoparticles of a first type. The immersion of step 1440 may last for approximately 8 hours. In step 1445 the substrate and structures on the substrate may be washed thoroughly with water. In step 1450 the substrate and structures on the substrate may be immersed in a solution containing nanoparticles of a second type. For example, the nanoparticles of a second type maybe positively charged 3 nm CdS particles. The substrate and structures on it may then be washed in step 1455 and dried in step 1460. One skilled in the art will appreciate that the temperatures, pressures, pHs, time periods, solution types, and material types described above are approximate only, and may be varied without departing from the scope of the present invention. In step 1465, bioelectronic cells are developed as discussed above in relation to FIG. 13. Once the bioelectronic cells have been developed, the cells are deposited on the nanodevice 1470. The bioelectronic cells are subsequently exposed to actuating chemicals 1475, resulting in a bioelectronic cell gated nanodevice according to the present invention. As will be understood by one skilled in the art, the bioelectronic cell gated nanodevice is fully integrable, meaning the device can in association with a variety of organisms sensitive to specific moieties.

As the miniaturization continues from micron-scale to nanoscale devices, the coupling of microorganisms and nanoscale devices allows for the development of highly sophisticated nanodevices. In one embodiment of the present invention, the bioelectronic cell gated nanodevice can be used to design complex sensors with high specificity and single-molecule sensitivity. For instance, in this embodiment, nanoparticle necklaces can be patterned on an array of independently powered electrode pairs with a variety of genetically engineered microorganisms on each electrode pair that function to target a specific chemical. When the chemical binds to the specific microorganism, that particular electrode pair will register a signal through a change in current as a cascade of biochemical processes, as will be understood by one of ordinary skill in the art. Eventually, in this embodiment, the microorganism will digest the chemical agent and regenerate to its initial state, creating a combinatorial sensor array with single-molecule sensitivity and high specificity.

In another embodiment of the present invention, the bioelectronic cell gated nanodevice can be used in association with a diode to create a micro-battery for powering devices. In this embodiment, the charge released will be transported in one direction because of the diode nature of the necklace, leading to an accumulation of charges, as will be understood by one of ordinary skill in the art. The configuration of this embodiment acts similar to a solid state solar cell; where such a polarization is obtained by a Schottky device or a p-n semiconductor junction.

It is contemplated and within the scope of the present invention that the bioelectronic cell gated nanodevice is adaptable to function in both wet and dry environments, as will be understood by one of ordinary skill in the art. Of course, a variety of types and sizes of nanoparticles beyond those described herein may be used for these purposes, and nanoparticles may be used alone or in combinations beyond those described herein. Likewise, methods of depositing nanoparticles may differ from those described herein, particularly with regard to the solutions and techniques used to deposit the nanoparticles. Further, the types of cells and/or organisms may vary from those described herein, and various combinations of cells and/or organisms may likewise be used in accordance with the present invention. As will be understood by one of skill in the art, the actuating chemical(s) may vary based upon types(s) of cells used. In fact, the type(s) of cells used may be selected based upon the desired actuating chemical(s) in some applications of the present invention.

The present invention has been described in relation to particular embodiments, which are intended in all respects to be illustrative rather than restrictive. Alternative embodiments will become apparent to those skilled in the art to which the present invention pertains without departing from its scope.

The invention claimed is:

1. A method for fabricating a bioelectronic cell gated nanodevice, the method comprising:
fabricating an electronic nanodevice;
developing cells for use in the bioelectronic cell gated nanodevice; and
depositing the cells on electronic nanodevice.

2. The method for fabricating a bioelectronic cell gated nanodevice of claim 1, further comprising:
exposing the bioelectronic cell gated nanodevice to at least one actuating chemical, the at least one actuating chemical being metabolized by the cells.

3. The method for fabricating a bioelectronic cell gated nanodevice of claim 2, wherein:
the at least one actuating chemicals comprises a form of alcohol.

4. The method for fabricating a bioelectronic cell gated nanodevice of claim 3, wherein:
the at least one actuating chemicals comprises methanol.

5. A method for fabricating a bioelectronic cell gated nanodevice, the method comprising:
suspending fiber materials in a first solution;
spinning the fibers from the solution on a substrate;
suspending a first type of nanoparticles in a second solution;
immersing the substrate and fibers in the second solution containing the suspended first type of nanoparticles, such that the suspended nanoparticles of the first type may adhere to the fibers;
developing cells for use in the bioelectronic cell gated nanodevice; and
depositing the cells on the substrate and nanoparticles.

6. The method for fabricating a bioelectronic cell gated nanodevice of claim 5, further comprising:
baking the substrate and fibers after spinning the fibers from the solution on the substrate.

7. The method for fabricating a bioelectronic cell gated nanodevice of claim 5, further comprising:
washing the substrate after immersing the substrate in the second solution containing the suspended nanoparticles of a first type; and
drying the substrate with the fibers and nanoparticles of a first type.

8. The method for fabricating a bioelectronic cell gated nanodevice of claim 5, further comprising:
exposing the bioelectronic cell gated nanodevice to at least one actuating chemicals, the at least one actuating chemical being metabolized by the cells.

9. The method for fabricating a bioelectronic cell gated nanodevice of claim 6, wherein:
the cells deposited comprise methylotrophic yeast cells.

10. A bioelectronic cell gated nanodevice comprising:
a substrate;
a pair of electrodes spaced apart on the substrate;
a nanoparticle necklace extending between the electrodes; and
a plurality of bioelectronic cells deposited on the substrate and the nanoparticle necklace.

11. The bioelectronic cell gated nanodevice of claim 10, further comprising:
at least one actuating chemicals.

12. The bioelectronic cell gated nanodevice of claim 11, wherein:
the at least one actuating chemicals comprises a form of alcohol.

13. The bioelectronic cell gated nanodevice of claim 12, wherein:
the at least one actuating chemicals comprises methanol.

14. The bioelectronic cell gated nanodevice of claim 10, wherein:
the plurality of bioelectronic cells allow increased current through the nanodevcice when the bioelectronic cells are exposed to the at least one actuating chemicals.

15. A bioelectronic cell gated nanodevice comprising:
a substrate comprising a layer of SiO₂ over a wafer of Si;
a pair of electrodes spaced apart on the substrate;
a nanoparticle necklace extending between the pair of electrodes; and
a plurality of bioelectronic cells deposited on the substrate and the nanoparticle necklace.

16. The bioelectronic cell gated nanodevice of claim 15, wherein:
the nanoparticle necklace comprises a plurality of Au nanoparticles.

17. The bioelectronic cell gated nanodevice of claim 16, wherein:
the plurality of bioelectronic cells comprise a plurality of methylotrophic yeast cells.

18. The bioelectronic cell gated nanodevice of claim 17, wherein:
the plurality of methylotrophic yeast cells comprise Pichia pastoris.

19. The bioelectronic cell gated nanodevice of claim 15, wherein:
the plurality of bioelectronic cells respond to exposure to an actuating chemical by altering their electronic properties.

20. The bioelectronic cell gated nanodevice of claim 19, wherein:
the bioelectronic cells allow increased current flow through the nanodevice when exposed to the actuating chemical.
